(19) United States
(12) Patent Application Publication
(10) Pub. No.: US 2024/0110989 A1
(43) Pub. Date: Apr. 4, 2024

(54) Method for Analyzing a State of an Exchangeable Battery Pack, Exchangeable Battery Pack, System, and Computer Program

(71) Applicant: Robert Bosch GmbH, Stuttgart (DE)

(72) Inventor: Andreas Gonser, Wolfschlugen (DE)

(21) Appl. No.: 18/473,820

(22) Filed: Sep. 25, 2023

(30) Foreign Application Priority Data
Oct. 4, 2022 (DE) 10 2022 210 477.3

(51) Int. Cl. G01R 31/3842; G01R 31/367; G01R 31/392; H01M 10/42

(52) U.S. Cl. CPC G01R 31/3842; G01R 31/367; G01R 31/392; H01M 10/4257; H01M 10/4285; H02J 7/005

(57) ABSTRACT

A method of analyzing a state of an exchangeable battery pack to make a determination of a remaining lifetime of an exchangeable battery pack more efficient includes an SoC determination step during which an SoC value of the exchangeable battery pack is determined, an SoH determination step during which a SoH value of the exchangeable battery pack is determined, and a remaining lifetime calculation step during which a remaining lifetime of the exchangeable battery pack is calculated taking into account the SoC value and the SoH value.

This application claims priority under 35 U.S.C. § 119 to application no. DE 10 2022 210 477.3, filed on 4 Oct. 2022 in Germany, the disclosure of which is incorporated herein by reference in its entirety.

### BACKGROUND

It is generally known that a battery pack, and at least one battery cell of the battery pack, ages over time due to storage and/or use. A loss of capacity of the battery pack has the consequence that a fully charged battery pack no longer has the original lifetime or capacity available and can provide it. In the case of battery packs permanently installed in devices and/or appliances, a continuous load profile, specifically any charging and discharging processes of the battery pack, can be recorded in order to monitor and preferably analyze a state of health of the battery pack at any time. In the case of battery packs designed as exchangeable battery packs, the recording of a continuous load profile has not been possible up to now. In the prior art, it is already known to consider only a SoC value when determining a remaining lifetime of an exchangeable battery pack.

### SUMMARY

A method for analyzing a state of an exchangeable battery pack is proposed, comprising:

an SoC determination step, during which an SoC value of the exchangeable battery pack is determined;

an SoH determination step, during which an SoH value of the exchangeable battery pack is determined; and

a calculating step, during which a remaining lifetime of the exchangeable battery pack is calculated considering the SoC value and the SoH value.

Such a method can be used to efficiently determine a remaining lifetime of an exchangeable battery pack. In addition, a SoH value and a SoC value can be determined, especially in exchangeable battery packs without continuous recording of a load profile, and those values can be taken into account when determining the remaining lifetime. Furthermore, within a short time, specifically in at most 30 sec, advantageously in at most 15 sec and preferably in at most 2 sec, the remaining lifetime can be determined. In addition, a calculation of the remaining lifetime of the exchangeable battery pack can be made more precise, i.e., more accurate.

Preferably, the present method is provided for determining and/or analyzing a remaining lifetime of the exchangeable battery pack, in particular at least one battery cell of the exchangeable battery pack, taking into account an aging of the exchangeable battery pack, in particular at least the battery cell of the exchangeable battery pack. Preferably, the proposed method is a method for determining the remaining lifetime of the exchangeable battery pack. In particular, aging of the exchangeable battery pack is manifested by at least one increase in a cell resistance of at least the battery cell and/or in an irreversible loss of a capacity of the exchangeable battery pack. The generally known SoH (“State of Health”) value indicates the remaining lifetime or usable capacity in relation to the original lifetime and/or capacity as a percentage. In particular, the SoH value indicates the current state of health of the exchangeable battery pack. For example, if an exchangeable battery pack arranged in an electric vehicle, e.g. an electric car or electric bicycle, can only be driven 450 km instead of the original 500 km, then the SoH value of that exchangeable battery pack is still 90% and the capacity of the exchangeable battery pack has decreased by 10% over time.

Furthermore, the generally known SoC (“State of Charge”) value describes a parameter for the state of charge of a battery pack, specifically the exchangeable battery pack. The SoC value indicates the still available capacity of the exchangeable battery pack in relation to the nominal value. The state of charge is given as a percentage of the fully charged state of the exchangeable battery pack. For example, an SoC value of 30% means that the exchangeable battery pack still has a residual charge of 30% relative to its full charge of 100%. For example, if an exchangeable battery pack comprises a battery capacity of 50 Ah and the electric vehicle travels 100 km/h and requires a current of 10 A, then the electric vehicle can travel 500 km during a trip of 5 h when the battery is fully charged (SoC value corresponding to 100%).

In the present case, the SoH value is to be taken into account in addition to the SoC value for analyzing the state of the exchangeable battery pack, specifically for determining the remaining lifetime of the exchangeable battery pack. According to the above example of the SoC value, taking into account the SoH value of, e.g. 90%, the electric vehicle would only be able to drive 450 km instead of 500 km, since the exchangeable battery pack has already aged by 10% and the capacity of the exchangeable battery pack has therefore decreased (SoH value is only 90%). Consequently, a precise and exact remaining lifetime can only be specified and/or determined when the SoC value and the SoH value are taken into account.

The exchangeable battery pack can be reversibly insertable into at least one consumer and/or reversibly connectable to the consumer. The consumer is preferably designed as an electrically operable consumer which can be supplied with electrical energy by means of at least the exchangeable battery pack. In particular, the consumer is designed as an electrical appliance. The consumer can, e.g., be designed as a hand-held machine tool. The term “hand-held machine tool” is in this context understood to mean a machine tool for machining workpieces, which can be transported and/or held by an operator without the need for a transport machine. The hand tool can be designed as a garden hand tool, e.g. a lawn trimmer, and more specifically as a brush cutter and/or a brush cutter, as a hedge trimmer, as a leaf blower and/or as a chainsaw, etc. Alternatively, the consumer can also be an electrical household appliance, in the case of, for example, an electrical cleaning appliance, in particular a robot vacuum cleaner, and/or a lamp and/or a remote control. It would also be conceivable for the consumer to be an at least partially electrically operable driving device, e.g., an electric bicycle, in particular an e-bike, and/or an electric scooter and/or an electric automobile. If the consumer is an electrically operable driving device, e.g. an e-bike, then the remaining lifetime is preferably designed in the form of a range. Preferably, the consumer is a consumer with constant current consumption and/or continuous current use. Furthermore, any other consumer design that appears advantageous to the skilled person is possible and conceivable.

The present disclosure further relates to a system having at least one consumer, in particular the aforementioned consumer, having an exchangeable battery pack which can be detachably connected to the consumer, in particular the aforementioned exchangeable battery pack. Preferably, the system comprises a control environment for determining the remaining lifetime of the exchangeable battery pack using said method. The term “control environment” is intended to mean an electronic unit, in particular a control unit, which is provided to control and/or regulate at least one function of the exchangeable battery pack, the consumer and/or a charger for the exchangeable battery pack. Advantageously, the control environment comprises at least one computing unit, in particular a processor, and preferably, in addition to the computing unit, at least one memory unit with a control and/or regulating program stored therein, which is intended to be executed by the computing unit. The storage unit can be designed as a digital storage medium, e.g., as a hard disk or the like.

The exchangeable battery pack can comprise a battery pack control unit, which can be at least partially part of or form the control environment. Preferably, the consumer comprises a consumer control unit that is at least partially part of or forms the control environment. In particular, the control environment controls and/or regulates the method for determining the remaining lifetime of the exchangeable battery pack. The battery pack control unit and/or at least the consumer control unit can/can at least partially control and/or regulate the method with the respective method steps for performing and/or executing the method for determining the remaining lifetime of the exchangeable battery pack. The battery pack control unit and at least the consumer control unit can communicate with each other, in particular wirelessly. Preferably, the system comprises a charger for at least the exchangeable battery pack. The charger can comprise a charger control unit. The charger control unit can be part of the control environment. The charger control unit can communicate with the battery pack control unit and/or at least the consumer control unit, advantageously wirelessly.

Particularly preferably, the control environment comprises a battery management system (BMS). A particularly efficient, accurate and user-friendly monitoring and/or analysis of at least one state of a battery, and more specifically of a rechargeable battery, can thereby be enabled and/or provided. In particular, the battery management system is an electronic control circuit that can monitor charging and/or discharging of battery packs, such as exchangeable battery packs, and/or ensure optimal use of battery cells of the battery pack. The battery pack control unit and/or at least the consumer control unit can at least partially feature or be designed as the battery management system. It may also be conceivable that the charger control unit at least partially features or is designed as the battery management system. Preferably, the battery management system is fully integrated into the exchangeable battery pack. The battery management system can be provided to monitor at least one state of the exchangeable battery pack and/or to perform measurements, e.g. at least one current and/or voltage measurement, in particular to determine at least one resistance, during a charging and/or discharging process of the exchangeable battery pack, in particular of at least one battery cell of the exchangeable battery pack, in order preferably to determine and/or calculate a residual capacity and/or a capacity of the exchangeable battery pack, the SoC value, the SoH value and/or the residual lifetime using the parameters, e.g., resistance parameters and/or temperature parameters, collected and/or recorded by the measurement.

The control environment can start and/or stop the method for analyzing the state of the exchangeable battery pack. Preferably, the consumer control unit communicates with at least the battery pack control unit for analyzing the state of the exchangeable battery pack, and does so when performing the method for the analysis of the state. Particularly preferably, the consumer control unit is provided to start and/or control and/or coordinate and/or terminate the method, in particular the individual method steps of the method. Alternatively and/or additionally, however, it is also conceivable that the battery pack control unit and/or the charger control unit is/are provided to start and/or regulate and/or coordinate and/or terminate the method, in particular the individual method steps of the method. It is conceivable that the battery pack control unit and/or the charger control unit are provided to perform the SoC determination step, the SoH determination step, and/or the remaining lifetime calculation step.

Advantageously, the control environment, in particular the consumer control unit, initiates the SoC determination step to determine the SoC value. During the SoC determination step, the consumer control unit preferably communicates with the battery pack control unit, in particular with the battery management system, in order to determine the SoC value. By means of the battery management system, at least the SoC value can be determined. By means of the battery management system, a capacity and/or residual capacity of the exchangeable battery pack and/or at least parameters, e.g., resistance parameters and/or temperature parameters, advantageously a current and/or at least a voltage of the exchangeable battery pack, in particular at least of the battery cell of the exchangeable battery pack, can be collected, on the basis of which at least the SoC value can be determined during the SoC determination step. For example, the consumer control unit can regulate and/or initiate and/or collecting measurements and/or acquisitions of parameters on the exchangeable battery pack. It would be conceivable for the consumer to comprise measuring units and/or sensors, which are advantageously part of the battery management system, in order to be able to perform measurements and/or obtain parameters on the exchangeable battery pack, specifically in an electrically connected state of the exchangeable battery pack with the consumer, in order in particular to be able to determine at least the SoC value and/or the SoH value.

The resistance parameter can, for example, be a voltage or a current or any other conceivable parameter from which and/or with which at least the resistance can be determined. A “temperature parameter” is a parameter associated with at least one temperature, whereby the temperature parameter can be any conceivable parameter using which and/or based on which the temperature can be determined. For example, the temperature parameter can be the temperature itself, advantageously a temperature of the battery cell measured at the intended installation location of a temperature sensor and/or a temperature measuring device, a time-dependent temperature curve and/or a temperature difference. Furthermore, the temperature parameter could be an electrical voltage and/or an electrical current strength, which is correlated with a temperature, a time-dependent temperature curve and/or a temperature difference.

Further, during the SoC determination step, communication can take place with at least one database environment for determining the SoC value. The database environment can be part of the control environment and at least partially integrated, e.g., into the exchangeable battery pack and/or into the consumer. Preferably, the database environment is at least largely or completely integrated into the exchangeable battery pack, in particular into the battery pack control unit. It would also be conceivable that the database environment is at least partially integrated into the charger, and/or the consumer, and/or a private, and/or public server, e.g., a private and/or public server on the internet. The database environment can also feature or be designed at least partially as a private and/or public cloud. Preferably, the database environment is designed as a dedicated computer system or as at least a part of a dedicated computer system.

The battery pack control unit and/or the consumer control unit and/or the charger control unit can/can communicate with the database environment, advantageously wirelessly. Communication between the battery pack control unit, the consumer control unit, the charger control unit, and/or at least the database environment can take place, for example, by means of a LAN, WLAN, WPAN, infrared, NFC, ZigBee, BLE, and/or Bluetooth connection and/or via the Internet.

To determine the SoC value, during the SoC determination step, the consumer control unit can communicate with the battery pack control unit, and preferably with the database environment at least partially integrated into the battery pack control unit, advantageously wirelessly. Preferably, the consumer control unit accesses the database environment at least partially integrated into the battery pack control unit, advantageously at least for determining the SoC value. SoC values and/or parameters correlated with the SoC value, such as the residual capacity and/or the capacity of the exchangeable battery pack, in particular a current value and/or at least one voltage value, in particular of at least one battery cell of the exchangeable battery pack, can be stored and/or saved in the database environment. For example, typical and known SoC characteristics of Li-ion battery cells could be stored and/or deposited in the database environment. Based on the data stored and/or deposited in the database environment, the consumer control unit and/or battery pack control unit can determine the SoC value during the SoC determination step.

Presently, the method for analyzing the state of the exchangeable battery pack comprises a plurality of method steps, specifically the SoC determination step, the SoH determination step, and at least the remaining lifetime calculation step. It would be conceivable for the method to comprise further method steps and/or method substeps. It is possible that the SoC determination step and/or at least the SoH determination step can be performed simultaneously, in parallel with each other. Particularly preferably, the remaining lifetime calculation step is performed only after the SoC determination step and at least the SoH determination step have been performed.

Advantageously, the control environment, in particular the consumer control unit, initiates the SoH determination step to determine the SoH value. Preferably, during the SoH determination step, the consumer control unit communicates with the battery pack control unit, in particular with the battery management system, to determine the SoH value. By means of the battery management system, at least the SoH value can be determined. By means of the battery management system, a resistance and/or a temperature and/or at least one parameter, for example the resistance parameter and/or the temperature parameter, advantageously a current and/or at least one voltage of the exchangeable battery pack, in particular at least of the battery cell of the exchangeable battery pack, can be collected, on the basis of which at least the SoH value can be determined during the SoH determination step.

Advantageously, the control environment, in particular the consumer control unit, initiates the remaining lifetime calculation step to calculate the remaining lifetime. Preferably, during the remaining lifetime calculation step, the consumer control unit communicates with at least one analysis environment, in particular with the battery management system, to determine the SoH value. By means of the battery management system, at least the SoH value can be determined. By means of the battery management system, a resistance and/or a temperature and/or at least one parameter, for example the resistance parameter and/or the temperature parameter, advantageously a current and/or at least one voltage of the exchangeable battery pack, in particular at least of the battery cell of the exchangeable battery pack, can be collected, on the basis of which at least the SoH value can be determined during the SoH determination step.

The consumer control unit and/or the battery pack control unit and/or the charger control unit could perform the remaining lifetime calculation step and calculate the remaining lifetime based on at least the SoC value and the SoH value. The remaining lifetime can be, for example, a time, a distance, specifically a range, a number of operations, or the like. Preferably, the consumer control unit and/or the battery pack control unit and/or the charger control unit communicates with an analysis device during the remaining lifetime calculation step for performing the remaining lifetime calculation step. In particular, the analysis device is part of the system. The analysis device can be at least partially part of the control environment. It would be conceivable for the analysis device to be at least partially or completely integrated into the exchangeable battery pack, in particular the battery pack control unit, the consumer, in particular the consumer control unit, and/or the charger, in particular the charger control unit. Alternatively and/or additionally, it would also be possible for the analysis device to be at least partially or fully integrated into an external device and/or an external server, such as a cell phone, a smartphone, a tablet, a laptop, and/or the like. For example, the SoC determination step and/or the SoH determination step could be performed by means of the consumer control unit and/or the battery pack control unit, and then the remaining lifetime calculation step could be performed by means of the analysis device, for example from the smartphone.

It is further proposed that during the SoH determination step, a consumer, in particular the aforementioned consumer, communicates with at least one database environment, in particular the aforementioned database environment, for determining the SoH value. This can further increase efficiency. In addition, data can be stored and/or deposited in a database environment in order to be able to determine a SoH value more quickly and/or more easily, in particular.

In particular, the consumer control unit communicates with the database environment. SoH values and/or parameters correlated with the SoH value, e.g., the resistance parameter and/or at least the temperature parameter of the exchangeable battery pack, in particular a current value and/or at least a voltage value, and/or at least a resistance and/or a temperature of the exchangeable battery pack, in particular of at least one battery cell of the exchangeable battery pack, can be stored and/or stored in the database environment. It would be conceivable for the charger control unit to store and/or save at least one SoH value of the exchangeable battery pack in the database environment during the charging process of the exchangeable battery pack.

In addition, it is proposed that during the SoH determination step, the SoH value is determined by a consumer, in particular the aforementioned consumer, in the state electrically connected to the exchangeable battery pack, in particular based on data provided by the exchangeable battery pack. An SoH value can thereby be determined based solely on a connection between a consumer and a battery pack. This in turn can increase an efficiency in a determination of a SoH value.

In particular, the data provided by the exchangeable battery pack is stored in the database environment. Particularly preferably, the database environment is integrated at least to a large extent and in particular completely into the exchangeable battery pack, in particular the battery pack control unit. To determine the SoH value, during the SoH determination step the consumer control unit can communicate with the battery pack control unit, and preferably with the database environment at least partially integrated into the battery pack control unit. Preferably, the consumer control unit accesses the database environment at least partially integrated into the battery pack control unit, at least for determining the SoH value. SoH values and/or parameters correlated with the SoH value, such as the resistance parameter and/or the temperature parameter of the exchangeable battery pack, in particular a current value and/or at least one voltage value, in particular of at least one battery cell of the exchangeable battery pack, can be stored and/or saved in the database environment. Based on the data stored and/or deposited in the database environment, the consumer control unit can determine the SoH value during the SoH determination step.

In order to further improve a determination of a SoH value, in particular to make it more efficient, and faster and/or less complicated, it is proposed that, during the SoH determination step, the SoH value is provided by the exchangeable battery pack. In particular, at least one SoH value, advantageously multiple SoH values are stored in the database environment. The SoH value can already be stored and/or deposited in the database environment based on a temporally earlier determination and/or calculation. It would also be conceivable that generally known SoH values for battery packs are stored and/or deposited in the database environment as a function of a service life and/or use of the battery pack. During the SoH determination step, the stored SoH value in the exchangeable battery pack can be accessed and made available for further processing.

It is further proposed that, during the SoH determination step, the SoH value is determined based on at least one collected resistance parameter of at least one battery cell of the exchangeable battery pack. This can further increase an efficiency and make a determination of a SoH value and thus also a remaining lifetime more precise. In particular, the resistance parameter is the resistance parameter specified hereinabove. Preferably, at least two resistance parameters of the battery cell of the exchangeable battery pack are collected. The at least two resistance parameters can be two different resistance parameters. For example, a first resistance parameter can be a current and a second resistance parameter can be a voltage. Alternatively and/or additionally, the at least two resistance parameters, in particular at least two identical or two different resistance parameters, can be collected at different timepoints during a collection step for collecting resistance parameters in the battery cell. For example, at least the first resistance parameter, in particular a first voltage, can be detected at a first timepoint, e.g., at the start of charging of a charging process of the battery pack, and at least the second resistance parameter, in particular a second voltage, can be collected at a second timepoint different from the first timepoint, e.g., during the charging process of the battery pack (during the collection step). Based on the first resistance parameter and at least the second resistance parameter, at least one resistance can be determined during the SoH determination step, based on which the SoH value can be determined. During the determination step, e.g., multiple resistances per battery cell could also be determined, e.g. example at least two resistances, advantageously at least four or six resistances, of the battery cell. When determining multiple resistances at different timepoints, a plurality of resistance parameters can be collected at the respective different timepoints during the collection step in order to be able to collect the plurality of resistances during the determination step.

Furthermore, the SoH value can be determined during the SoH determination step based on at least one resistance parameter and advantageously multiple resistance parameters collected from multiple battery cells of the exchangeable battery pack. By collecting multiple identical and/or different types of resistance parameters per battery cell at different timepoints, multiple resistances (specifically, at least two resistances per battery cell) can be determined at different timepoints during the determination step in order to determine the SoH value from them. It is conceivable that the determination of the resistance and/or the determination of the temperature is performed for all battery cells of the exchangeable battery pack and a calculation of the SoH value be limited to a smaller number of battery cells.

Alternatively, it is proposed that, during the SoH determination step, the SoH value is estimated based on at least one change of a measured voltage of at least one battery cell of the exchangeable battery pack over time at the same current flow. This can simplify a method and make a SoH determination step for determining a SoH value faster and/or less complicated and/or simpler.

It would be conceivable that, during the remaining lifetime calculation step, the remaining lifetime is only calculated on the basis of the SoH value and the SoC value. In addition, however, it is proposed that, during the remaining lifetime calculation step, a current measurement is performed to collect a current parameter of the exchangeable battery pack, and the current parameter is taken into account when calculating the remaining lifetime. Calculation of a remaining lifetime of an exchangeable battery pack can be further optimized thereby. The control environment, in particular the consumer control unit and/or the battery pack control unit, and/or the analysis device can initiate and/or control and/or regulate and/or perform the current measurement during the remaining lifetime calculation step. Preferably, during the remaining lifetime calculation step, the consumer control unit and/or the battery pack control unit controls the battery management system to perform the current measurement. It would also be conceivable that the current parameter of the exchangeable battery pack is already known and the current measurement has already been performed during the SoC determination step and/or the SoH determination step. The current parameter could be stored in the database environment. During the remaining lifetime calculation step, the consumer control unit and/or the battery pack control unit and/or the analysis device could access and/or communicate with the database environment to collect the current parameter.

It is further proposed that, during the calculation step, a voltage measurement is performed to collect a voltage parameter of the exchangeable battery pack, and the voltage parameter is taken into account when calculating the remaining lifetime. This can increase an efficiency in a flow of a method for analyzing a state of an exchangeable battery pack. The control environment, in particular the consumer control unit and/or the battery pack control unit, and/or the analysis device can initiate and/or control and/or regulate and/or perform the voltage measurement during the remaining lifetime calculation step. Preferably, during the remaining lifetime calculation step, the consumer control unit and/or the battery pack control unit controls the battery management system to perform the voltage measurement. It would also be conceivable that the voltage parameter of the exchangeable battery pack is already known and the voltage measurement has already been performed during the SoC determination step and/or the SoH determination step. The voltage parameter could be stored in the database environment. During the remaining lifetime calculation step, the consumer control unit and/or the battery pack control unit and/or the analysis device for collecting voltage parameters could access and/or communicate with the database environment.

If the method comprises an output step for outputting the remaining lifetime, a user convenience and efficiency can be further increased. In addition, a remaining lifetime of an exchangeable battery pack can be communicated and/or conveyed to a user. Advantageously, the output step with regard to the chronological progression of the method takes place after the remaining lifetime calculation step. The battery pack control unit and/or the consumer control unit can cause an acoustic and/or optical output of the remaining lifetime during the output step.

Preferably, the system comprises a remaining lifetime output for outputting a remaining lifetime. The remaining lifetime output can, for example, be arranged on the consumer or at least partially integrated into the consumer. It is further proposed that the exchangeable battery pack comprises at least one output unit, which is provided to output the remaining lifetime during the output step. In other words, a remaining lifetime can be output and provided directly at an exchangeable battery pack. Thus, in addition to an efficiency, in terms of a product efficiency, a user comfort can be increased. In particular, the output unit is part of the remaining lifetime output or is designed as such. Preferably, at least the battery pack control unit controls and/or regulates the output of the remaining lifetime by means of the output unit. Further, the consumer control unit can provide data correlated with the determined remaining lifetime, in particular the remaining lifetime, to the battery pack control unit for outputting the remaining lifetime.

In addition, the disclosure relates to a computer program comprising instructions which, when the computer program is executed by a computer, cause the computer to perform the described method for analyzing a state of an exchangeable battery pack, in particular said exchangeable battery pack.

The method for analyzing a state of an exchangeable battery pack, the exchangeable battery pack, the system, and/or the computer program shall/shall not be limited in this regard to the application and embodiment described above. In particular, the method, the exchangeable battery pack, the system, and/or the computer program can/may comprise a number of individual elements, components, units, and method steps other than a number specified herein to perform a function described herein. In addition, for the ranges of values specified in this document, values within the specified limits are also to be considered disclosed and usable as desired.

### BRIEF DESCRIPTION OF THE DRAWINGS

Further advantages follow from the description of the drawings hereinafter. The drawings illustrate two exemplary embodiments of the disclosure. The drawings, the description, and the claims contain numerous features in combination. The skilled person will appropriately also consider the features individually and combine them into additional advantageous combinations.

Shown are:

FIG. 1 a system featuring a battery pack designed as an exchangeable battery pack, a charger and a consumer,

FIG. 2 a schematic flowchart of a method for analyzing a state of the battery pack, and specifically for determining a remaining lifetime of the battery pack,

FIG. 3 a schematic flowchart of a method for determining a SoH value of the battery pack, and

FIG. 4 a system in an alternative exemplary embodiment, the system featuring an exchangeable battery pack, a charger, a consumer, and a database environment comprising a cloud.

### DETAILED DESCRIPTION

The following drawings are schematic and not to scale.

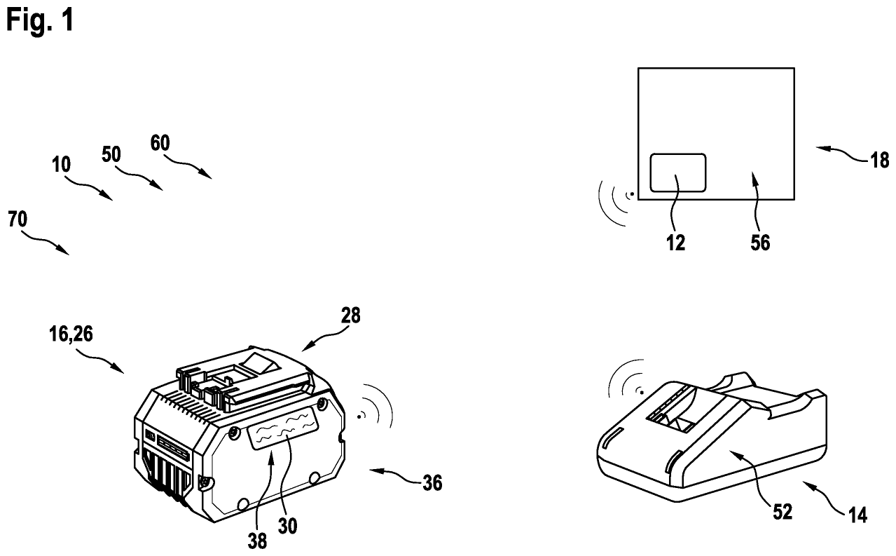

FIG. 1 shows a system 10 with a charger 14 for a battery pack 16. The system 10 comprises the battery pack 16, which is designed as an exchangeable battery pack 26. The exchangeable battery pack 26 is reversibly insertable into at least one consumer 18 and/or reversibly connectable to the consumer 18. In the present case, the consumer 18 is part of the system 10. The consumer 18 is an electric appliance, such as a hand-held power tool, electric household appliance, such as a robot vacuum cleaner or a lamp, or an electrically operable driving device, such as an electric bicycle or an electric scooter. Further, the consumer 18 is a consumer with constant current consumption and/or continuous current use. By means of the battery pack 16, the consumer 18 can be at least partially supplied with electrical energy and/or can be operated in at least one operating state by means of electrical energy of the battery pack 16.

The system 10 comprises a control environment 50. The battery pack 16 comprises a battery pack control unit 36. The battery pack control unit 36 is part of the control environment 50. The charger 14 comprises a charger control unit 52. The charger control unit 52 is part of the control environment 50. Further, the consumer 18 comprises a consumer control unit 56. The consumer control unit 56 is part of the control environment 50. The battery pack control unit 36, charger control unit 52, and/or the consumer control unit 56 are provided to communicate with or among each other (i.e., in the present case wirelessly).

In the present embodiment, the control environment 50 is provided to perform a method of analyzing a state of the battery pack 16, specifically the exchangeable battery pack 26. Presently, the control environment 50 is provided for performing a method for determining a remaining lifetime of the battery pack 16. The remaining lifetime is, for example, a time, a distance, specifically a range, a number of operations, or the like.

To at least partially perform the method of analyzing the state of the battery pack 16, the control environment 50 comprises a battery management system 60. The battery management system 60 is provided to monitor at least one state of the battery pack 16 and/or to perform measurements, e.g., at least one current and/or voltage measurement, in particular for determining at least one resistance, during a charging and/or discharging process of the battery pack 16, preferably in order to determine and/or calculate a residual capacity and/or a capacity of the battery pack 16a, a SoC value, a SoH value and/or the residual lifetime using the parameters collected and/or detected by the measurement, e.g., resistance parameters and/or temperature parameters. In this exemplary embodiment, the battery management system 60 is at least partially integrated into the consumer control unit 56 and at least partially integrated into the battery pack control unit 36. It would also be conceivable for the battery management system 60 to be fully integrated into the consumer control unit 56.

The control environment 50 can start and/or stop the method for analyzing the state of the battery pack 16. Further, a computer program 70 comprises instructions that, when the computer program 70 is executed by a computer of the control environment 50, cause the computer to perform the method of analyzing the state of the battery pack 16. The computer program 70 is at least partially integrated into the consumer control unit 56, the battery pack control unit 36, and/or the charger control unit 52.

In the present case, the consumer control unit 56 communicates with at least the battery pack control unit 36 for analyzing the state of the battery pack 16, and specifically when performing the method for the analysis of the state. The consumer control unit 56 is provided to start and/or control and/or coordinate and/or terminate the method, and at least individual method steps of the method. Alternatively and/or additionally, the battery pack control unit 36, and/or the charger control unit 52 could be provided for starting, and/or controlling, and/or coordinating, and/or terminating the method, specifically at least individual method steps of the method. In the present case, the consumer control unit 56 is provided to regulate, and/or initiate, and/or control measurements, and/or parameter collection in the battery pack 16. The consumer 18 comprises measuring units and/or sensors, which are part of the battery management system 60, in order to perform measurements and/or parameter collection, e.g., resistance parameters and/or temperature parameters, in the battery pack 16, specifically in an electrically connected state of the battery pack 16 with the consumer 18.

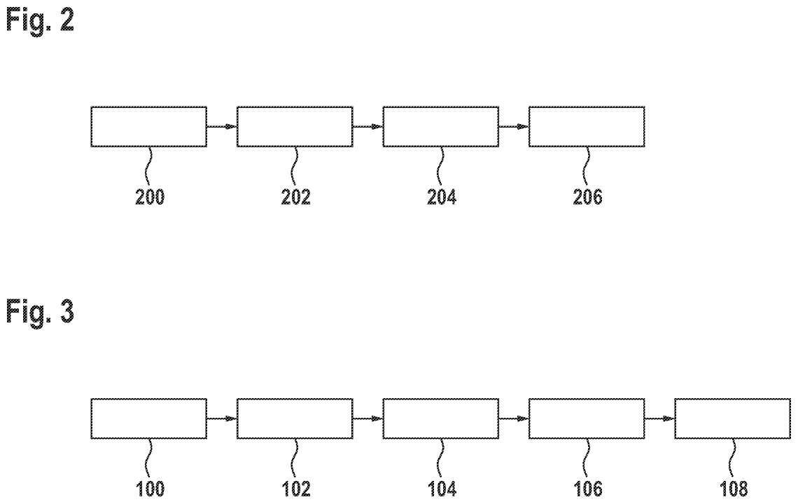

The method for analyzing the state of the battery pack can comprise multiple method steps and/or method substeps. In the present case, the method comprises an SoC determination step 200, during which an SoC value of the battery pack 16 is determined (see FIG. 2). In the present case, during the SoC determination step 200, the consumer control unit 56 communicates with the battery pack control unit 36 to determine the SoC value. By means of the battery management system 60, a capacity and/or remaining capacity of the battery pack 16 is determinable during the SoC determination step 200.

According to FIG. 2, with respect to a chronological progression of the method, after the SoC determination step 200, an SoH determination step 202 is performed, during which an SoH value of the battery pack 16 is determined. In the following, a determination of the SoH value of the battery pack 16 or the various possibilities for determining the SoH value will be discussed in detail. For this purpose, FIG. 3 shows a schematic method flowchart of a method for determining the SoH value of the battery pack 16.

Referring to FIG. 3, the method for determining the SoH value of the battery pack 16 comprises a collection step 100 for collecting at least one resistance parameter. The resistance parameter is, e.g., a voltage or a current. In this exemplary embodiment, a voltage change of at least one battery cell of the battery pack 16 at different charging currents or discharging currents is collected during the collection step 100. In the present case, at least two resistance parameters of the battery cell are collected during the collection step 100. For example, during the collection step 100, at least a first resistance parameter is a first voltage at a first timepoint, e.g., at the start of charging of a charging process of the battery pack 16, and the second resistance parameter is a second voltage at a second timepoint different from the first timepoint, e.g., during the charging process of the battery pack 16. In this exemplary embodiment, the battery pack 16 comprises a plurality of battery cells. Furthermore, during the collection step 100, at least one resistance parameter is collected for each battery cell of the battery pack 16.

As shown in FIG. 3, with respect to a chronological progression of the method for determining the SoH value of the battery pack 16, the collection step 100 is followed by a determination step 102 for determining at least one resistance based on the resistance parameter. In the present case, the resistor is an internal resistor of the battery cell. During the determination step 102, multiple resistances of the battery cell could be determined. In this exemplary embodiment, at least two resistances of the battery cell are determined at different timepoints during the determination step 102. When determining a plurality of resistances at different timepoints, a plurality of resistance parameters can be collected at the respective different timepoints during the collection step 100, so that the plurality of resistances can in turn be determined during the determination step 102. To provide a particularly efficient method, the determination step 102 determines the resistance of a battery cell of the battery pack 16 that features the lowest voltage. The determination and/or selection of the weakest battery cell of the battery pack 16 can be based on the resistance parameters, e.g. voltage, collected during the collection step 100. The battery pack control unit 36 and/or the consumer control unit 56 and/or the charger control unit 52 is provided to determine and/or define and/or detect the weakest battery cell of the battery pack 16.

With respect to the chronological progression of the method, a further collection step 104 for collecting at least one temperature parameter is performed after the determination step 102. The temperature parameter is a parameter associated with at least one temperature, in which case the temperature parameter can be any conceivable parameter, using which and/or based on which the temperature can be determined. For example, the temperature parameter is the temperature itself, a time-dependent temperature curve and/or a temperature difference. Furthermore, in a further determination step 106, which follows the further collection step 104, at least one temperature is determined based on the temperature parameter. In the present case, at least one temperature parameter is collected and a temperature is determined for each battery cell of the battery pack 16.

In the present case, the battery pack 16 is designed to collect the at least one resistance parameter and to collect the at least one temperature parameter. Further, the battery management system 60, which is at least partially integrated into the battery pack control unit 36, is designed to collect the at least one resistance parameter and to collect the at least one temperature parameter. The battery pack control unit 36 could independently perform and/or start the steps of collecting the at least one resistance parameter and collecting the at least one temperature parameter. Alternatively, the consumer control unit 56 is arranged to start and/or control the collection step 100, the determination step 102, the further collection step 104 and/or the further determination step 106.

According to FIG. 3, after the further determination step 106, a calculation step 108 is performed, during which a SoH value of the battery pack 16 is calculated taking into account the at least one resistance and at least one temperature. In order to provide a particularly efficient and fast method, the determination of the resistance is performed in the present case for all battery cells of the battery pack 16, although the calculation step 108 is limited to a smaller number of battery cells. Alternatively, the calculation step 108 could be performed for all battery cells of the battery pack 16 for which at least one resistance has been determined.

The calculation step 108 can be performed by the battery pack control unit 36, the charger control unit 52, and/or the consumer control unit 56. Presently, the system 10 comprises an analysis device 12 for performing at least the calculation step 108. In this exemplary embodiment, the analysis device 12 is at least partially, and further fully, integrated into the consumer 18, and more specifically the consumer control unit 56. Alternatively and/or additionally, it would also be possible for the analysis device 12 to be at least partially or fully integrated into an external device and/or an external server, e.g. a smartphone, a tablet, a laptop, and/or the like.

Further, during the calculation step 108, a machine learning method is used to calculate the SoH value. In the present example, the analysis device 12 uses a machine learning algorithm during the calculation step 108. To increase an efficiency of at least the calculation step 108, the machine learning method is self-learning.

After successful calculation of the SoH value, the SoH value can be stored and/or saved in a database environment 28. In the present embodiment, the database environment 28 is at least largely or completely integrated into the battery pack 16, and further integrated into the battery pack control unit 36. Alternatively and/or additionally, the database environment 28 could also be at least partially integrated into the consumer 18, specifically the consumer control unit 56 and/or the charger 14, specifically the charger control unit 52.

During the SoH determination step 202, the consumer 18 communicates with at least the database environment 28 to determine the SoH value. During the SoH determination step 202, the SoH value can be provided by the battery pack 16. The consumer 18, and specifically the consumer control unit 56 retrieves the SoH value from the database environment 28 during the SoH determination step 202. Alternatively, at least the resistance parameter, the resistance, the temperature parameter and/or the temperature can be stored and/or stored in the database environment 28, which, for example, could be collected and/or determined by the collection step 100, the determination step 102, the further collection step 104, and/or the further determination step 106. If the consumer 18 is electrically connected to the battery pack 16 or communicates wirelessly with the battery pack 16, the consumer 18, specifically the consumer control unit 56 can determine the SoH value during the SoH determination step 202 based on data provided by the battery pack 16, specifically the data stored in the database environment 28.

According to the method just described in FIG. 3, during the SoH determination step 202, the SoH value can be determined based on at least one determined resistance parameter of at least one battery cell of the battery pack 16. Alternatively, during the SoH determination step 202, the SoH value could also be estimated based on at least one change in a measured voltage of at least one battery cell of the battery pack 16 over time at the same current flow. Estimation would simplify the SoH determination step 202, but it can make the determined SoH value somewhat less accurate than after the calculation already described. Consequently, multiple approaches are possible for determining the SoH value during the SoH determination step 202.

If the SoC determination step 202 and the SoH determination step 202 have been performed according to the method shown in FIG. 2, a remaining lifetime calculation step 204 is then performed, during which a remaining lifetime of the battery pack 16 is calculated taking into account the SoC value and the SoH value. Further, during the remaining lifetime calculation step 204, a current measurement is performed to collect a current parameter of the battery pack 16, and the current parameter is taken into account when calculating the remaining lifetime. Alternatively, during the remaining lifetime calculation step 204, a voltage measurement is performed to collect a voltage parameter of the battery pack 16, and the voltage parameter is taken into account when calculating the remaining lifetime.

The remaining lifetime calculation step 204 can be performed by the battery pack control unit 36, the charger control unit 52, and/or the consumer control unit 56. Presently, the remaining lifetime calculation step 204 is performed using the analysis device 12. In this regard, the battery pack control unit 36 communicates with the analysis device 12. Presently, the battery pack control unit 36 communicates with the consumer control unit 56 during the remaining lifetime calculation step 204.

To output remaining lifetime to a user, the system 10 features a remaining lifetime output 38 for outputting a remaining lifetime. Furthermore, the method according to FIG. 2 comprises an output step 206 for outputting the remaining lifetime. The output step 206 occurs after the remaining lifetime calculation step 204. The battery pack control unit 36 and/or the consumer control unit 56 can cause the remaining lifetime to be output. In this exemplary embodiment, the battery pack 16 comprises an output unit 30 that is provided to output the remaining lifetime during the output step 206. The output unit 30 is part of the remaining lifetime output 38. Alternatively and/or additionally, the consumer 18 could also comprise an output unit for outputting the remaining lifetime, which is part of the remaining lifetime output 38. The output of the remaining lifetime can be audible and/or visual to the user.

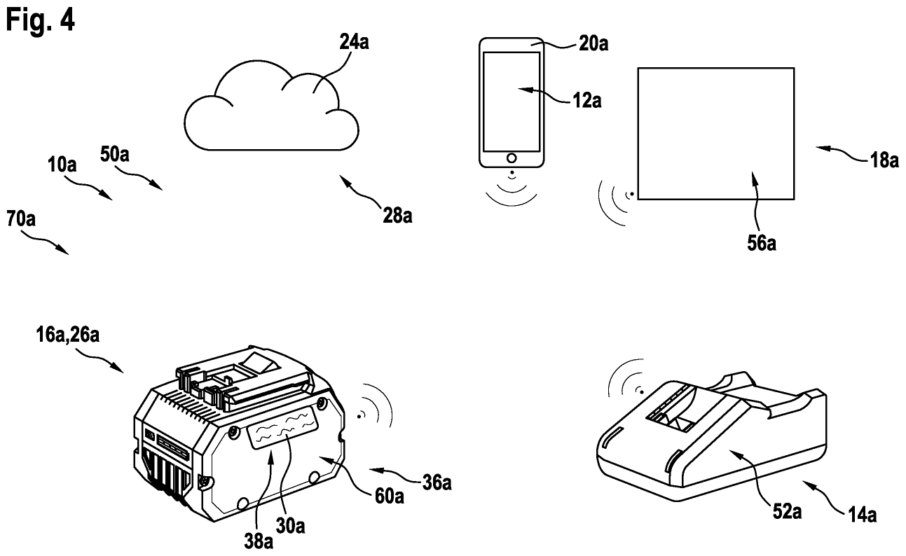

FIG. 4 shows another exemplary embodiment of the disclosure. The following descriptions are essentially limited to the differences between the exemplary embodiments, whereby reference can be made to the description of the exemplary embodiment in FIGS. 1 to 3 with regard to components, features and functions that remain the same. To distinguish the exemplary embodiments, the letter a is inserted into the reference signs of the exemplary embodiment in FIG. 4. With regard to components with the same designation, in particular with regard to components with the same reference signs, reference can in principle also be made to the drawings and/or the description of the embodiment in FIGS. 1 to 3.

FIG. 4 shows a system 10a in an alternative exemplary embodiment. The system 10a comprises a battery pack 16a, which is also designed as an exchangeable battery pack 26a, a charger 14 for the battery pack 16, and a consumer 18a. Further, the system 10a comprises a control environment 50a. The battery pack 16a comprises a battery pack control unit 36a. The battery pack control unit 36a is part of the control environment 50a. The charger 14a comprises a charger control unit 52a. The charger control unit 52a is part of the control environment 50a. Further, the consumer 18a comprises a consumer control unit 56a. The consumer control unit 56a is part of the control environment 50a. The battery pack control unit 36a, charger control unit 52a and/or the consumer control unit 56a are provided to communicate with each other, respectively, wirelessly.

To at least partially perform a method for analyzing the state of the battery pack 16a, the control environment 50a comprises a battery management system 60a. The difference to the previously described exemplary embodiment according to FIGS. 1 to 3 is that the battery management system 60a is fully integrated into the battery pack 16a in the present case. Furthermore, in this exemplary embodiment, the battery pack 16a is provided to perform and/or control necessary measurements and/or collection of parameters of at least one battery cell of the battery pack 16 itself, independently of a consumer control unit 56a. Presently, the battery management system 60a integrated into the battery pack 16a, specifically the battery pack control unit 36a manages a monitoring and/or analysis of the state of at least one cell, preferably all cells of the battery pack 16a. Furthermore, in this exemplary embodiment, the charger 14 is additionally designed to collect the at least one resistance parameter and/or to collect the at least one temperature parameter. The charger control unit 52 communicates with the battery pack control unit 36a either in an electrically connected state, such as during charging, or wirelessly.

In addition, the present exemplary embodiment differs from the exemplary embodiment according to FIGS. 1 and 3 in a database environment 28a. Whereas in the exemplary embodiment according to FIGS. 1 and 3 the database environment 28 was fully integrated into the battery pack 16a, the database environment 28a is at least partially integrated in a private and/or public server, e.g., a private and/or public server on the Internet. In the present embodiment, the database environment 28a features a private and/or public cloud 24a.

Further, in the present embodiment, the system 10a comprises an external device 20a, which in this exemplary embodiment is designed as a cell phone. An analysis device 12a of the system 10a is in this case at least partially arranged in the external device 20a. In contrast to the exemplary embodiment shown in FIGS. 1 and 3, based on the integrated analysis device 12a, the external device 20a respectively executes and/or performs a calculation step for calculating a SoH value of the battery pack 16a and/or a remaining lifetime calculation step for calculating the remaining lifetime based on at least the SoH value and a SoC value of the battery pack 16a. To collect the SoH value and/or the SoC value and/or at least one parameter correlated with the SoH value and/or the SoC value, the external device 20a communicates, in this case wirelessly, with the battery pack 16a, the consumer 18a, the charger 14a and/or the database environment 28a. The external device 20a is adapted to perform, based on data provided by the battery pack 16a, the consumer 18a, the charger 14a, and/or the database environment 28a, the calculation step for calculating the SoH value of the battery pack 16a and/or the remaining lifetime calculation step for calculating the remaining lifetime. After calculating the SoH value and/or the remaining lifetime, the external device 20a can transmit data to the battery pack 16a and/or the consumer 18a to, e.g., indicate the remaining lifetime. Alternatively and/or additionally, the external device 20a could also output, for example display, the remaining lifetime.

What is claimed is:

1. A method of analyzing a state of an exchangeable battery pack, comprising:
determining a SoC value of the exchangeable battery pack;
determining a SoH value of the exchangeable battery pack; and
calculating a remaining lifetime of the exchangeable battery pack taking into account the SoC value and the SoH value.

2. The method according to claim 1, wherein determining the SoH value comprises:
communicating, using a consumer, with at least one database environment to determine the SoH value.

3. The method according to claim 1, wherein determining the SoH value comprises:
determining the SoH value based on data provided by the exchangeable battery pack using a consumer electrically connected to the exchangeable battery pack.

4. The method according to claim 1, wherein determining the SoH value comprises:
providing the SoH value with the exchangeable battery pack.

5. The method according to claim 1, wherein determining the SoH value comprises:
determining the SoH value based on at least one collected resistance parameter of at least one battery cell of the exchangeable battery pack.

6. The method according to claim 1, wherein determining the SoH value comprises:
estimating the SoH value based on at least a change of a measured voltage of at least one battery cell of the exchangeable battery pack over time at the same current flow.

7. The method according to claim 1, further comprising:
measuring a current of the exchangeable battery pack to obtain a parameter of the current; and
taking into account the parameter of the current when calculating the remaining lifetime.

8. The method according to claim 1, further comprising:
measuring a voltage of the exchangeable battery pack to obtain a parameter of the voltage; and
taking into account the parameter of the voltage when calculating the remaining lifetime.

9. The method according to claim 1, further comprising:
outputting the remaining lifetime.

10. An exchangeable battery pack comprising at least one battery pack control unit configured to communicate with an analysis device, the analysis device configured to perform the method according to claim 1.

11. The exchangeable battery pack according to claim 10, further comprising:
at least one output unit configured to output the calculated remaining lifetime.

12. A system, comprising:
the exchangeable battery pack according to claim 11; and
at least one consumer configured to be detachably connected to the exchangeable battery pack, wherein the at least one consumer includes (i) a remaining lifetime output configured to output the remaining lifetime, and (ii) the analysis device in the form of a control environment.

13. The system according to claim 12, wherein the consumer is an electric appliance, in particular a hand-held machine tool or an electric bicycle, and comprises a consumer control unit which at least partially forms the control environment, which in particular comprises a battery management system.

14. The system according to claim 12, wherein:
the control environment comprises a battery management system; and
the battery management system is fully integrated into the exchangeable battery pack.

15. A computer program comprising instructions that, when the computer program is executed by a computer, prompt the computer to perform the method according to claim 1.
